(19) United States
(12) Patent Application Publication
(10) Pub. No.: US 2026/0066163 A1
(43) Pub. Date: Mar. 5, 2026

(54) SUPERCONDUCTING MAGNET DEVICE

(71) Applicant: SUMITOMO HEAVY INDUSTRIES, LTD., Tokyo (JP)

(72) Inventors: Atsushi HASHIMOTO, Yokosuka-shi (JP); Jun YOSHIDA, Yokosuka-shi (JP)

(21) Appl. No.: 19/385,129

(22) Filed: Nov. 10, 2025

Related U.S. Application Data
(63) Continuation of application No. PCT/JP2024/031481, filed on Sep. 2, 2024.

(30) Foreign Application Priority Data
Sep. 21, 2023 (JP) 2023-156267

(51) Int. Cl. H01F 6/04; C30B 15/30; H01F 6/02; H01F 6/06

(52) U.S. Cl. CPC H01F 6/04; C30B 15/305; H01F 6/02; H01F 6/06

(57) ABSTRACT

A superconducting magnet device includes: a cryostat that includes an inner peripheral wall disposed in a radially outward direction of a bore to surround the bore and an outer peripheral wall disposed in the radially outward direction of the inner peripheral wall to surround the inner peripheral wall, and that provides a vacuum environment in an internal space defined between the inner peripheral wall and the outer peripheral wall; a pair of saddle superconducting coils disposed to face each other with the bore interposed between the pair of saddle superconducting coils, and each being exposed to the vacuum environment, in the internal space; and a support frame that is disposed in the radially outward direction of the pair of saddle superconducting coils in the internal space, and that supports the pair of saddle superconducting coils.

### CROSS-REFERENCE TO RELATED APPLICATIONS

This is a bypass continuation of International PCT Application No. PCT/JP2024/031481, filed on September 2, 2024, which claims priority to Japanese Patent Application No. 2023-156267, filed on September 21, 2023, which are incorporated by reference herein in their entirety.

### BACKGROUND

### Technical Field

A certain embodiment of the present invention relates to a superconducting magnet device.

### Description of the Related Art

The superconducting magnet device is used as a magnetic field generation source of a single crystal pulling device according to a magnetic field applied Czochralski (MCZ) method. The single crystal pulling device generally includes a single crystal pulling furnace and a cryostat that is disposed to surround a single crystal pulling furnace and that accommodates a plurality of superconducting coils. Typically, a saddle coil or a round coil is used for the superconducting coil. Heat convection in a melt in the pulling furnace can be suppressed by the strong magnetic field generated by the superconducting coil.

### SUMMARY

One or more embodiments provide a superconducting magnet device including: a cryostat that includes an inner peripheral wall disposed in a radially outward direction of a bore to surround the bore and an outer peripheral wall disposed in the radially outward direction of the inner peripheral wall to surround the inner peripheral wall, and that provides a vacuum environment in an internal space defined between the inner peripheral wall and the outer peripheral wall; a pair of saddle superconducting coils disposed to face each other with the bore interposed between the pair of saddle superconducting coils, and each being exposed to the vacuum environment, in the internal space; and a support frame that is disposed in the radially outward direction of the pair of saddle superconducting coils in the internal space, and that supports the pair of saddle superconducting coils.

### BRIEF DESCRIPTION OF THE DRAWINGS

FIG. 1 illustrates a sectional view schematically illustrating a single crystal pulling device mounted with a superconducting magnet device, according to an embodiment.

FIG. 2 illustrates another sectional view schematically illustrating the single crystal pulling device mounted with the superconducting magnet device, according to the embodiment.

FIG. 3 illustrates a perspective view schematically illustrating an appearance of the superconducting magnet device, according to the embodiment.

FIG. 4 illustrates a perspective view schematically illustrating a superconducting coil disposition in the superconducting magnet device, according to the embodiment.

FIG. 5 illustrates a sectional view schematically illustrating the superconducting magnet device, according to the embodiment.

FIG. 6 illustrates a schematic diagram illustrating a part of a developed view of a saddle superconducting coil and a support frame, according to the embodiment when viewed from a radially inward direction.

FIG. 7 illustrates a front view schematically illustrating the support frame, according to the embodiment when viewed from a radially outward direction.

FIG. 8 illustrates a perspective view schematically illustrating another example of the superconducting coil disposition in the superconducting magnet device, according to the embodiment.

### DETAILED DESCRIPTION

In an existing design of the single crystal pulling device using the saddle coil as the superconducting coil, a coil bobbin used for manufacturing the saddle coil is used as a support structure of the saddle coil as it is. The saddle coil is accommodated in the cryostat together with the bobbin. While the saddle coil is wound around an outside of the bobbin, the single crystal pulling furnace to which the magnetic field is to be applied by the superconducting coil is disposed inside the cryostat, that is, inside the bobbin. That is, the bobbin is disposed between a location to which the magnetic field is applied and the saddle superconducting coil. In such a configuration, the saddle superconducting coil is disposed far from the magnetic field application location by a space occupied by the bobbin. According to the Biot–Savart law, a magnetic field in which a coil is generated is proportional to the inverse cube of the distance. Therefore, when the coil is separated from the magnetic field application location, the magnetizing force of the coil required to generate the magnetic field at the same magnitude can be significantly increased even when the distance is short. This may cause an increase in the number of required superconducting wire materials, and may cause an increase in manufacturing costs of the superconducting magnet device, which is undesirable.

In addition, in the single crystal pulling device, a magnetic shield is often installed to surround an outer periphery of the cryostat to reduce a leaked magnetic field. In the superconducting coil, a corresponding strong electromagnetic force acts in a direction toward the magnetic shield, that is, in a radially outward direction, when the magnetic field is generated. The electromagnetic force acts to separate the superconducting coil from the bobbin in a configuration in which the bobbin is used as the support structure of the saddle superconducting coil as described above. In order to avoid this, it may be necessary to add a structural member or to reinforce a support structure to press the superconducting coil against the bobbin. A weight increase or an enlargement caused by this can also increase the manufacturing costs of the superconducting magnet device.

It is desirable to provide a superconducting magnet device having an improved support structure for a saddle superconducting coil.

Hereinafter, embodiments for implementing the present invention will be described in detail with reference to drawings. In the description and drawings, the same reference numerals are assigned to the same or equivalent components, members, and processing, and repeated description is omitted as appropriate. A scale or shape of each part that is illustrated in the drawings is conveniently set for ease of description and is not interpreted as being limited unless otherwise specified. The embodiment is merely an example and does not limit the scope of the present invention. All features or combinations thereof described in the embodiments are not necessarily essential to the invention.

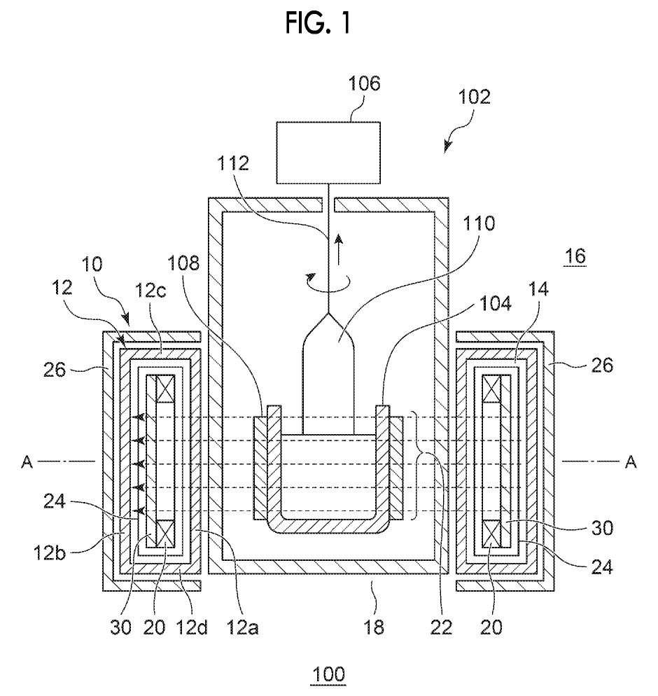

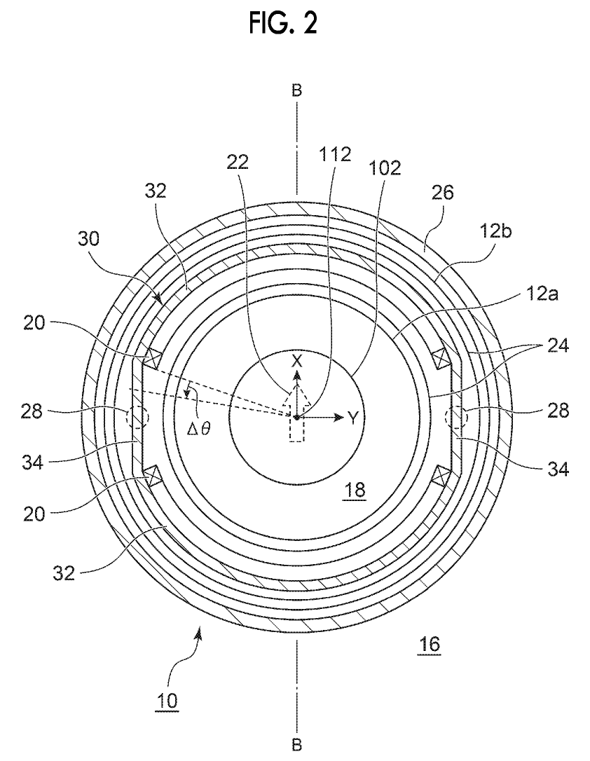

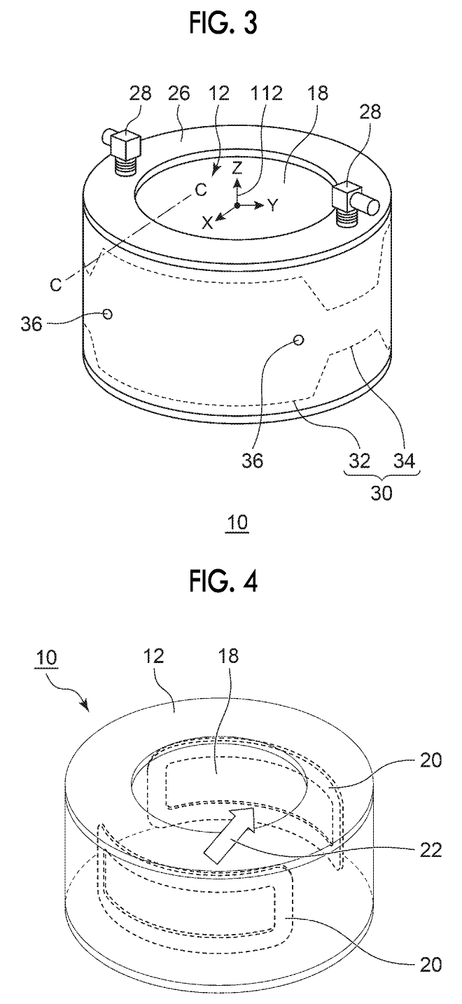

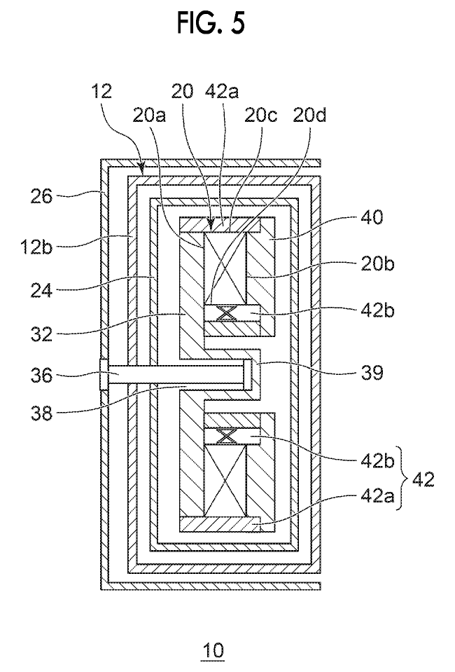

FIGS. 1 and 2 are sectional views schematically illustrating a single crystal pulling device 100 mounted with a superconducting magnet device 10 according to an embodiment. FIG. 3 is a perspective view schematically illustrating an appearance of the superconducting magnet device 10 according to the embodiment. FIG. 4 is a perspective view schematically illustrating a superconducting coil disposition in the superconducting magnet device 10 according to the embodiment. FIG. 5 is a sectional view schematically illustrating the superconducting magnet device 10 according to the embodiment. FIG. 1 illustrates a B-B cross section in FIG. 2, and FIG. 2 illustrates an A-A cross section in FIG. 1. In addition, FIG. 5 illustrates a C-C cross section in FIG. 3.

The single crystal pulling device 100 includes a single crystal pulling furnace 102 and the superconducting magnet device 10. The single crystal pulling device 100 is, for example, a silicon single crystal pulling device using a horizontal magnetic field MCZ (HMCZ) method.

As illustrated in FIG. 1, the single crystal pulling furnace 102 includes a crucible 104, a single crystal pulling mechanism 106, and a heater 108.

The crucible 104 is a container that stores a molten material (for example, molten silicon), and is formed of, for example, quartz.

The single crystal pulling mechanism 106 is a driving device that pulls a single crystal 110 upward along a single crystal pulling shaft 112 from the molten material in the crucible 104, and includes a pulling drive source disposed above and outside the single crystal pulling furnace 102. The single crystal pulling shaft 112 is an axis extending in a vertical direction (that is, a direction perpendicular to a horizontal plane). The single crystal pulling mechanism 106 is configured to pull up the single crystal 110 while rotating the single crystal 110 around the single crystal pulling shaft 112.

The heater 108 is disposed around the crucible 104 in the single crystal pulling furnace 102, and heats the crucible 104. The heating by the heater 108 maintains a molten state of the molten material in the crucible 104.

The superconducting magnet device 10 includes a cryostat 12, a pair of saddle superconducting coils 20, a heat shield 24, a magnetic shield 26, and a support frame 30. The superconducting magnet device 10 is used as a magnetic field generation source of the single crystal pulling device 100.

The cryostat 12 has an internal space 14 that is isolated from a surrounding environment 16 surrounding the cryostat 12, and the saddle superconducting coil 20, the heat shield 24, and the support frame 30 are disposed in the internal space 14. The internal space 14 is a cylindrical space. The cryostat 12 is a heat insulating vacuum chamber, and during an operation of the superconducting magnet device 10, a cryogenic temperature vacuum environment suitable for bringing the saddle superconducting coil 20 into a superconducting state is provided in the internal space 14 of the cryostat 12.

The cryostat 12 has a cylindrical shape that defines a bore 18 inward and that extends along a center axis of the bore 18, that is, the single crystal pulling shaft 112. When the superconducting magnet device 10 is mounted on the single crystal pulling device 100, the single crystal pulling furnace 102 is disposed in the bore 18. The bore 18 is a part of the surrounding environment 16 surrounding the cryostat 12 (that is, is outside the cryostat 12), and is a space having a columnar shape, for example, surrounded by the cryostat 12.

The cryostat 12 includes an inner peripheral wall 12a disposed in a radially outward direction of the bore 18 to surround the bore 18, and an outer peripheral wall 12b disposed in the radially outward direction of the inner peripheral wall 12a to surround the inner peripheral wall 12a. Both the inner peripheral wall 12a and the outer peripheral wall 12b have a cylindrical shape, and the saddle superconducting coil 20, the heat shield 24, and the support frame 30 are disposed therebetween. The inner peripheral wall 12a and the outer peripheral wall 12b are coaxially disposed around the single crystal pulling shaft 112. In addition, the cryostat 12 includes a top plate 12c and a bottom plate 12d that connect the inner peripheral wall 12a and the outer peripheral wall 12b to each other at upper and lower sides. The top plate 12c and the bottom plate 12d have an annular shape and have a substantially flat surface. The internal space 14 of the cryostat 12 is defined between the inner peripheral wall 12a and the outer peripheral wall 12b in a radial direction, and is defined between the top plate 12c and the bottom plate 12d in the vertical direction (a direction of the single crystal pulling shaft 112).

At least the inner peripheral wall 12a of the cryostat 12 is formed of a non-magnetic material (for example, a non-magnetic metallic material such as stainless steel) not to hinder the saddle superconducting coil 20 from generating a magnetic field in the bore 18. Other parts of the cryostat 12, that is, the outer peripheral wall 12b, the top plate 12c, and the bottom plate 12d, may also be formed of the same material as the inner peripheral wall 12a.

The pair of saddle superconducting coils 20 face each other with the bore 18 interposed therebetween, and are disposed symmetrically with respect to the single crystal pulling shaft 112. Each of the saddle superconducting coils 20 is curved to be recessed toward the bore 18, and is, for example, curved in an arc shape along a cylindrical shape of the cryostat 12. The two saddle superconducting coils 20 have the same shape and the same size.

One of the two saddle superconducting coils 20 generates a magnetic field inward in the radial direction, that is, in a direction toward the single crystal pulling shaft 112, and the other saddle superconducting coil 20 generates a magnetic field in the radially outward direction, that is, in a direction away from the single crystal pulling shaft 112. The pair of saddle superconducting coils 20 generate a synthetic magnetic field 22 by superimposing the magnetic fields. The synthetic magnetic field 22 is perpendicular to the single crystal pulling shaft 112 on the single crystal pulling shaft 112.

Hereinafter, for convenience of description, as illustrated in FIGS. 2 and 3, an XY coordinate plane perpendicular to the single crystal pulling shaft 112 is considered. An origin of the coordinate plane is on the single crystal pulling shaft 112, an X-axis extends in a direction of the synthetic magnetic field 22 on the single crystal pulling shaft 112, and a Y-axis is perpendicular to the single crystal pulling shaft 112 and the X-axis. The single crystal pulling shaft 112 can also be regarded as a Z-axis.

The heat shield 24 is disposed in the internal space 14 of the cryostat 12 to surround the saddle superconducting coil 20 and the support frame 30. The heat shield 24 is provided to prevent radiant heat from intruding from the surrounding environment 16 into the saddle superconducting coil 20.

In order to suppress the magnetic field generated by the saddle superconducting coil 20 from leaking to the outside, the magnetic shield 26 covers the outer peripheral wall 12b, the top plate 12c, and the bottom plate 12d of the cryostat 12. The magnetic shield 26 is formed of a magnetic material such as iron, for example, and is disposed adjacent to the outer peripheral wall 12b, the top plate 12c, and the bottom plate 12d of the cryostat 12. The magnetic shield 26 does not cover the inner peripheral wall 12a of the cryostat 12 so as not to hinder the saddle superconducting coil 20 from generating a magnetic field in the bore 18.

A pair of cryocoolers 28 for cooling the pair of saddle superconducting coils 20, the heat shield 24, and the support frame 30 are installed in the cryostat 12. FIGS. 2 and 3 illustrate an exemplary disposition of the cryocooler 28 in the cryostat 12.

The cryocooler 28 is, for example, a two-stage Gifford-McMahon (GM) cryocooler, and includes a first cooling stage that is cooled to a first cooling temperature and a second cooling stage that is cooled to a second cooling temperature lower than the first cooling temperature. The cryocooler 28 is installed in the cryostat 12 such that the first cooling stage and the second cooling stage are disposed in the internal space 14 of the cryostat 12. The heat shield 24 is cooled to the first cooling temperature by the first cooling stage of the cryocooler 28, and the saddle superconducting coil 20 and the support frame 30 are cooled to the second cooling temperature by the second cooling stage of the cryocooler 28. The first cooling temperature may be, for example, in a range of 30 K to 80 K, and the second cooling temperature may be, for example, in a range of 3 K to 20 K.

Each of the pair of saddle superconducting coils 20, the heat shield 24, and the support frame 30 is disposed in the internal space 14 to be exposed to the vacuum environment. These internal components of the cryostat 12 are cooled by a so-called conductive cooling by the cryocooler 28. The heat shield 24 is thermally coupled to the first cooling stage of the cryocooler 28 via a first heat transfer member, and is directly cooled by the first cooling stage. The saddle superconducting coil 20 is thermally coupled to the second cooling stage of the cryocooler 28 via a second heat transfer member, and is directly cooled by the second cooling stage.

Therefore, in this embodiment, the cryostat 12 does not use immersion cooling by which the saddle superconducting coil 20 is immersed in a cryogenic temperature liquid refrigerant such as liquid helium to be cooled. The cryostat 12 is not provided with a liquid refrigerant tank that accommodates the saddle superconducting coil 20 together with the cryogenic temperature liquid refrigerant. The support frame 30 is adjacent to the saddle superconducting coil 20 in the internal space 14 of the cryostat 12, and does not form a closed section surrounding the saddle superconducting coil 20.

One of the pair of cryocoolers 28 is installed on one side of the cryostat 12 with respect to the bore 18 between the pair of saddle superconducting coils 20 in a circumferential direction of the cryostat 12. On the other hand, the other cryocooler 28 is installed in the cryostat 12 on an opposite side with respect to the bore 18 between the pair of saddle superconducting coils 20 in the circumferential direction of the cryostat 12. For example, as illustrated, the pair of cryocoolers 28 may be disposed on the Y-axis. The pair of cryocoolers 28 may be disposed such that one is on a +Y side and the other is on a −Y side with the single crystal pulling shaft 112 interposed therebetween. The cryocooler 28 is installed on the top plate 12c of the cryostat 12 as an example. As illustrated in FIG. 3, a portion of the cryocooler 28 protrudes upward from an upper plate of the magnetic shield 26 adjacent to the top plate 12c.

With such a symmetrical disposition of the cryocoolers 28, a heat transfer distance from each of the cryocoolers 28 to the saddle superconducting coil 20 can be made equal. Accordingly, the pair of saddle superconducting coils 20 can be uniformly cooled.

In addition, the strong magnetic field generated by the saddle superconducting coil 20 affects the behavior of the cryocooler 28 and may cause a decrease in the cooling capacity in some cases. The magnetic field is strongest on the X-axis and weakest on the Y-axis on the XY plane. Therefore, the installation position of the cryocooler 28 described above is selected to be a location at which the magnetic field is weak. Therefore, it is possible to reduce an adverse effect caused by the magnetic field on the cryocooler 28.

In order to achieve such an advantageous effect, it is not essential that two cryocoolers 28 are strictly disposed on the Y-axis. As illustrated in FIG. 2, the cryocooler 28 may be disposed at an angular position separated by an angle Δθ from a circumferential end portion of the saddle superconducting coil 20 in the circumferential direction. The angle Δθ may be, for example, at least 4 degrees. In this manner, the cryocooler 28 is disposed away from the saddle superconducting coil 20 in the circumferential direction. Therefore, it is possible to reduce an adverse effect of the magnetic field on the cryocooler 28.

The support frame 30 is disposed in the radially outward direction of the pair of saddle superconducting coils 20 in the internal space 14 of the cryostat 12, and supports the pair of saddle superconducting coils 20. The support frame 30 is formed in a ring shape to surround the bore 18. The support frame 30 is a structure that rigidly couples the saddle superconducting coil 20 to hold the relative position between the saddle superconducting coils 20 against an electromagnetic force acting on the saddle superconducting coil 20 during the operation of the superconducting magnet device 10, and can be referred to as a rigid frame. The support frame 30 is formed of a metal material such as stainless steel or another suitable high-strength material to realize required rigidity.

The support frame 30 includes a pair of coil mounts 32 having a curved shape based on a curvature of the saddle superconducting coil 20, and a pair of linear coupling beams 34 coupling the pair of coil mounts 32.

The coil mount 32 is a part of the support frame 30 on which the saddle superconducting coil 20 is installed. The coil mount 32 is curved along the saddle superconducting coil 20, is adjacent to the saddle superconducting coil 20 in the radially outward direction, and supports the saddle superconducting coil 20. In this manner, the coil mount 32 has a curved shape that is fitted to the saddle superconducting coil 20. Therefore, when an electromagnetic force acts on the saddle superconducting coil 20 during the operation of the superconducting magnet device 10, the coil mount 32 effectively supports the electromagnetic force, and thus it is possible to suppress deformation that may occur in the saddle superconducting coil 20.

One coupling beam 34 couples one end portions of the coil mount 32 to each other, and the other coupling beam 34 couples the other end portions of the coil mount 32 to each other. The coupling beam 34 is not a location at which the saddle superconducting coil 20 is installed, and thus it is not necessary to have a curved shape along the saddle superconducting coil 20 as in the coil mount 32. The coupling beam 34 has a flat shape. Therefore, the coupling beam 34 is easier to manufacture than in the case of a curved shape. This can lead to a reduction in manufacturing costs of the support frame 30.

As illustrated in FIG. 3, the pair of linear coupling beams 34 may have a smaller dimension in the vertical direction (that is, the direction of the single crystal pulling shaft 112) than the pair of coil mounts 32. Accordingly, this allows weight saving of the coupling beam 34 and the support frame 30, as compared with a case where vertical dimensions of the coupling beam 34 and the coil mount 32 are the same. In addition, the disposition space for the cryocooler 28 can be secured above the coupling beam 34 by utilizing the fact that a height of the coupling beam 34 is lower than a height of the coil mount 32.

As an alternative example, the coupling beam 34 may be curved in an arc shape along the cylindrical shape of the cryostat 12, in the same manner as in the coil mount 32. The support frame 30 may be formed in a ring shape from the coil mount 32 and the coupling beam 34. In addition, the coil mount 32 and the coupling beam 34 may be prepared as separate members, and may be coupled to each other to form the support frame 30. Alternatively, the support frame 30 may be formed as a single structure in which the coil mount 32 and the coupling beam 34 are integrated.

As illustrated in FIGS. 3 and 5, the superconducting magnet device 10 is provided with a plurality of horizontal load support bodies 36 that support the support frame 30 in a horizontal direction. The horizontal load support body 36 supports an electromagnetic force acting on the saddle superconducting coil 20 in the radially outward direction during the operation of the superconducting magnet device 10.

The horizontal load support body 36 has a rod-like shape extending in the radial direction of the cryostat 12, is supported by the magnetic shield 26 at one end thereof, and is supported by the coil mount 32 of the support frame 30 at the other end thereof. The horizontal load support body 36 extends from the magnetic shield 26 through the outer peripheral wall 12b of the cryostat 12 and the heat shield 24 to the coil mount 32. The electromagnetic force acting on the saddle superconducting coil 20 in the radially outward direction is supported by using the horizontal load support body 36 with the magnetic shield 26 as a fulcrum.

At least a part of the horizontal load support body 36, for example, an end portion of the horizontal load support body 36, may be formed of a metal material such as stainless steel. In order to suppress input heat from the magnetic shield 26 through the horizontal load support body 36 to the saddle superconducting coil 20, at least a part of the horizontal load support body 36, for example, a rod-shaped body connecting both ends of the horizontal load support body 36, may be formed of a heat insulating material such as a fiber reinforced plastic.

The support frame 30 is provided with a recessed portion 38 formed to face from an outer peripheral surface of the support frame 30 in a radially inward direction. The recessed portion 38 is provided in the coil mount 32 of the support frame 30 to receive an end portion of the horizontal load support body 36 on the support frame 30 side. The support frame 30 is supported by the horizontal load support body 36 in the recessed portion 38. In addition, the recessed portion 38 is formed in the coil mount 32 as a protrusion 39 that protrudes in the radial direction into an inner space of the saddle superconducting coil 20.

In this manner, since a part of the horizontal load support body 36 is accommodated in the recessed portion 38 of the support frame 30, a total radial dimension of the horizontal load support body 36 and the support frame 30 can be reduced. This can lead to downsizing of the superconducting magnet device 10. At the same time, a length of the horizontal load support body 36 in the radial direction can be made long. Accordingly, it is possible to ensure a heat insulating distance by the horizontal load support body 36 between the magnetic shield 26 and the support frame 30, and it is possible to reduce a thermal load on the saddle superconducting coil 20.

Two horizontal load support bodies 36 are disposed for one saddle superconducting coil 20. When an electromagnetic force acts on the saddle superconducting coil 20, a bending stress is likely to occur in a coil at a corner portion of the coil (that is, an end portion of the coil in the circumferential direction of the cryostat 12). In order to effectively suppress the bending deformation of the coil due to the bending stress, the horizontal load support body 36 may be disposed in the vicinity of the corner portion of the saddle superconducting coil 20. Therefore, the recessed portion 38 that receives the horizontal load support body 36 may be formed at a circumferential end portion of the coil mount 32 of the support frame 30 in the circumferential direction. In addition, when necessary, an additional (that is, third) horizontal load support body 36 may be disposed for each saddle superconducting coil 20.

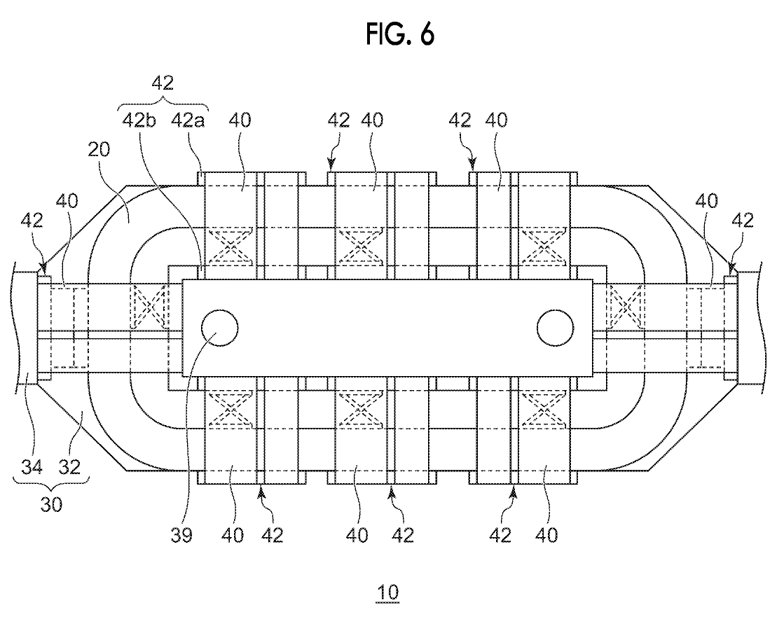

FIG. 6 is a schematic diagram illustrating a part of a deployment diagram of the saddle superconducting coil 20 and the support frame 30 according to the embodiment, when viewed from the radially inward direction. As illustrated in FIGS. 5 and 6, a first support 40 and a second support 42 are attached to the support frame 30 to fix the saddle superconducting coil 20 to the support frame 30.

The first support 40 is a plate disposed in the radially inward direction of the saddle superconducting coil 20, and is attached to the coil mount 32 of the support frame 30 to press the saddle superconducting coil 20 against the support frame 30 in the radially outward direction. Each saddle superconducting coil 20 has a first coil end surface 20a facing the radially outward direction and a second coil end surface 20b facing the radially inward direction, and is in contact with the coil mount 32 at the first coil end surface 20a and is in contact with the first support 40 at the second coil end surface 20b. The first support 40 is attached to the support frame 30 to sandwich the saddle superconducting coil 20 between the two coil end surfaces. The first support 40 may be attached to the support frame 30 via the second support 42, or may be directly attached to the support frame 30.

In this manner, the saddle superconducting coil 20 is pressed against the support frame 30 by the first support 40. Therefore, the displacement of the saddle superconducting coil 20 in the radial direction of the cryostat 12 can be suppressed, and a radial position of the saddle superconducting coil 20 on the support frame 30 can be held.

In addition, each saddle superconducting coil 20 has two coil side surfaces connecting the first coil end surface 20a and the second coil end surface 20b to each other, that is, a first coil side surface 20c on a coil outer peripheral side and a second coil side surface 20d on a coil inner peripheral side. The second support 42 is attached to the support frame 30 to sandwich the saddle superconducting coil 20 between the two coil side surfaces.

The second support 42 includes a first member 42a and a second member 42b, the first member 42a comes into contact with the first coil side surface 20c, and the second member 42b comes into contact with the second coil side surface 20d. The first member 42a is a wall that covers a portion of the first coil side surface 20c, and the second member 42b is a wall that covers a portion of the second coil side surface 20d. Each of the first member 42a and the second member 42b is attached to the support frame 30. In order to sandwich the saddle superconducting coil 20 between the first member 42a and the second member 42b, one of the first member 42a and the second member 42b, for example, the second member 42b, includes a pressing tool such as a leveling block, a screw jack, and a plate spring.

In this manner, the saddle superconducting coil 20 is sandwiched by the second support 42. Therefore, it is possible to suppress the bending of the saddle superconducting coil 20 that may occur when an electromagnetic force acts on the saddle superconducting coil 20.

By providing both the first support 40 and the second support 42, the displacement and the deformation of the saddle superconducting coil 20 with respect to the support frame 30 are effectively suppressed. This is helpful for suppressing the generation of quenching in the saddle superconducting coil 20.

As illustrated in FIG. 6, the coil supports are provided not only in upper and lower portions of the saddle superconducting coil 20 but also in corner portions. In this manner, the first support 40 and the second support 42 are provided at a plurality of locations along the saddle superconducting coil 20. Therefore, the support frame 30 can be firmly fixed over the entire circumference of the saddle superconducting coil 20.

The first support 40 and the second support 42 are discretely provided at a plurality of locations, instead of being continuously provided along the entire circumference of the saddle superconducting coil 20. By adopting such a division structure, the first support 40 and the second support 42 are easily manufactured.

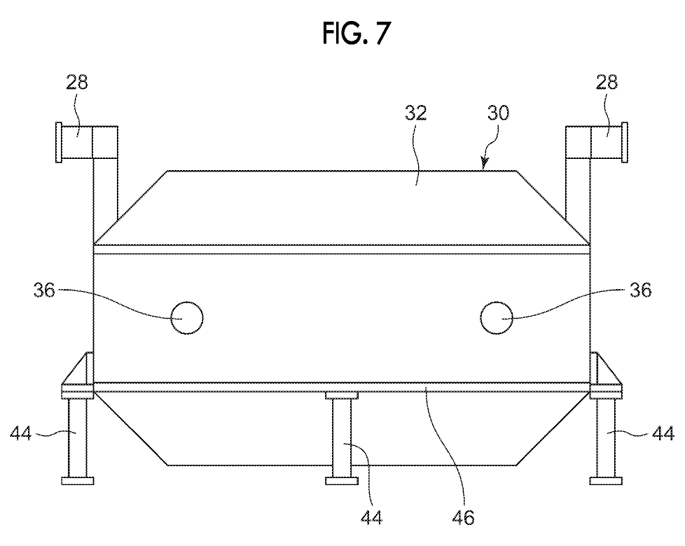

FIG. 7 is a front view schematically illustrating the support frame 30 according to the embodiment when viewed from the radially outward direction. The superconducting magnet device 10 is provided with a plurality of vertical load support bodies 44 that support the support frame 30 in the vertical direction. Self-weight acting on the internal components of the cryostat 12, such as the saddle superconducting coil 20, can be supported by the vertical load support body 44. The plurality of vertical load support bodies 44 may be disposed at equal angular intervals in the circumferential direction of the cryostat 12. For example, six vertical load support bodies 44 may be disposed at intervals of 60 degrees. In addition, FIG. 7 illustrates the cryocooler 28, together with the support frame 30.

The vertical load support body 44 has a rod-like shape extending in the vertical direction, is supported on a bottom surface of the cryostat 12 at one end thereof, and is supported by the coil mount 32 of the support frame 30 at the other end thereof. At least a part of the vertical load support body 44, for example, an end portion of the vertical load support body 44, may be formed of a metal material such as stainless steel. In addition, in order to suppress the input heat from the cryostat 12 to the saddle superconducting coil 20 through the vertical load support body 44, at least a part of the vertical load support body 44, for example, a rod-shaped body connecting both ends of the vertical load support body 44, may be formed of an insulating material such as a fiber reinforced plastic.

As illustrated in FIG. 7, the support frame 30 includes a rib 46 formed in the radially outward direction from the outer peripheral surface of the support frame 30, and is supported by the vertical load support body 44 with the rib 46. The rib 46 extends in the circumferential direction on an outer peripheral surface of the coil mount 32 of the support frame 30. In this manner, the vertical load support body 44 is coupled to the rib 46 extending in the horizontal direction. Therefore, the rib 46 serves as a so-called buffer material, and it is possible to reduce a direct load on the vertical load support body 44 due to an impact load (for example, an electromagnetic force of the saddle superconducting coil 20, an impact that can occur during transport of the superconducting magnet device 10, and the like) on the support frame 30.

In addition, although not illustrated, the cryostat 12 may be provided with other components such as a current introduction terminal connected to the saddle superconducting coil 20, a vacuum exhaust port for evacuating the cryostat 12, and a measurement port connected to a measuring instrument in the cryostat 12. At least one of the current introduction terminal, the vacuum exhaust port, and the measurement port may be installed on an upper surface or a lower surface of the cryostat 12.

As described at the beginning of the present specification, in the existing design of the single crystal pulling device using the saddle superconducting coil, the support structure of the saddle superconducting coil is often attached to the saddle superconducting coil in the radially inward direction. In this case, the saddle superconducting coil is disposed away from the single crystal pulling furnace to which the magnetic field is to be applied in the radial direction by the space occupied by the support structure. Since the magnetic field generated by the coil is proportional to the inverse cube of the distance, the required exciting force of the coil can be significantly increased as the saddle superconducting coil is separated from the single crystal pulling furnace. That is, the magnetic field generation efficiency tends to be low. This may increase the number of superconducting wire materials required for the coil, and may further increase the manufacturing costs of the superconducting magnet device, which is undesirable.

On the other hand, according to the embodiment, since the saddle superconducting coil 20 is supported by the support frame 30 in the radially outward direction, the saddle superconducting coil 20 can be disposed close to the bore 18. Therefore, the magnetic field generation efficiency can be improved, the amount of the superconducting wire material can be reduced, and the manufacturing costs of the superconducting magnet device 10 can be reduced.

Further, during the operation of the superconducting magnet device 10, a strong electromagnetic force corresponding to a strong magnetic field generated by the saddle superconducting coil 20 acts on the saddle superconducting coil 20 in a direction toward the magnetic shield 26, that is, in the radially outward direction. The saddle superconducting coil 20 is strongly pulled toward the magnetic shield 26.

In the existing design described above, since the support structure of the saddle superconducting coil is provided in a radially inward direction thereof, the force acting on the coil acts in the radially outward direction to separate the coil from the support structure. In order to avoid the separation of the coil from the support structure, it may be necessary to add a structural member or to reinforce the support structure. The weight increase or enlargement caused by this may increase the manufacturing costs of the device, which is undesirable.

On the other hand, according to the embodiment, the force acting on the saddle superconducting coil 20 in the radially outward direction acts to press the saddle superconducting coil 20 against the support frame 30. Therefore, contrary to the related art, the support frame 30 can effectively support the saddle superconducting coil 20 with a relatively simple configuration. As a result, it is also possible to achieve weight saving of the superconducting magnet device 10.

Typically, an outer diameter of the cryostat 12 mounted on the single crystal pulling device 100 is set to be approximately 1.5 times an inner diameter (that is, a diameter of the bore 18). In order to adapt the cryostat 12 having such a radial dimension, the pair of saddle superconducting coils 20 are preferably disposed in the range of 1.05 to 1.32 times the diameter of the bore 18 in the internal space 14 of the cryostat 12. In other words, a lower limit value of an inner diameter of the saddle superconducting coil 20 may be set to 1.05 times the diameter of the bore 18 of the cryostat 12. In addition, an upper limit value of an outer diameter of the saddle superconducting coil 20 may be set to 1.32 times the diameter of the bore 18 of the cryostat 12.

The heat shield 24 is disposed in the radially inward direction of the saddle superconducting coil 20 in the internal space 14. In cooling the saddle superconducting coil 20 to a lower temperature than the heat shield 24, it is desired to reliably avoid physical contact between the saddle superconducting coil 20 and the heat shield 24. From such a viewpoint, the lower limit value of 1.05 times described above is determined.

The heat shield 24 is also disposed in the radially outward direction of the support frame 30 in the internal space 14. The support frame 30 is cooled to a lower temperature than the heat shield 24, together with the saddle superconducting coil 20. It is desired to reliably avoid physical contact between the support frame 30 and the heat shield 24. In addition, in order to provide a desired rigidity, the support frame 30 needs to have a size to some extent in the radial direction. From such a viewpoint, the upper limit value of 1.32 times described above is defined.

In the same manner, the pair of linear coupling beams 34 may be disposed in the internal space 14 of the cryostat 12 in a range of 1.05 to 1.32 times the diameter of the bore 18. In this manner, in consideration of avoiding the physical contact between the coupling beam 34 and the heat shield 24 and ensuring the heat insulation therebetween, a lower limit value of a dimension of the coupling beam 34 in the radially inward direction may be set to 1.05 times the diameter of the bore 18, and an upper limit value of the dimension of the coupling beam 34 in the radially outward direction may be set to 1.32 times the diameter of the bore 18.

The present invention has been described above based on the examples. It is understood by those skilled in the art that the present invention is not limited to the above embodiments, various design changes can be made, various modification examples are possible, and such modification examples are also within the scope of the present invention. Various features described in relation to an embodiment are also applicable to other embodiments. A new embodiment resulting from a combination has the effect of each of the embodiments that are combined.

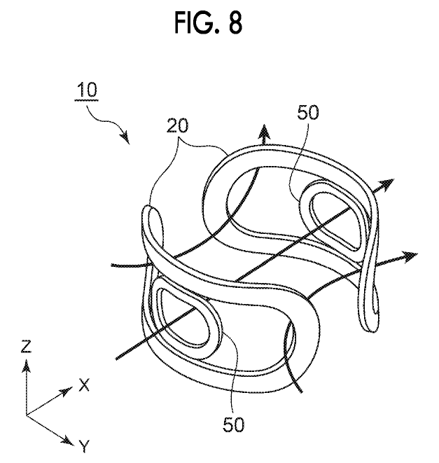

FIG. 8 is a perspective view schematically illustrating another example of the superconducting coil disposition in the superconducting magnet device 10 according to the embodiment. As illustrated, in addition to the pair of saddle superconducting coils 20, the superconducting magnet device 10 may include an additional superconducting coil 50 for assisting in adjusting the magnetic field distribution in the superconducting magnet device 10. The additional superconducting coil 50 may be a coil smaller than the saddle superconducting coil 20, and may be disposed inside the saddle superconducting coil 20. The additional superconducting coil 50 may be a circular coil or may be a saddle coil. Both the saddle superconducting coil 20 and the additional superconducting coil 50 may be supported by the support frame 30 described above.

The single crystal pulling device on which the superconducting magnet device 10 according to the embodiment is mounted may be a single crystal pulling device for producing a single crystal of a semiconductor material other than silicon or of another material.

When applicable, the superconducting magnet device 10 may be mounted on a device other than the single crystal pulling device. The superconducting magnet device 10 can be mounted on a high magnetic field utilization device as a magnetic field source of the high magnetic field utilization device and can generate a high magnetic field required for the device.

Although the present invention has been described using specific words and phrases based on the embodiment, the embodiment merely illustrates one aspect of the principle and application of the present invention, and many modification examples and changes in disposition are allowed without departing from the concept of the present invention specified in the claims.

The present invention can be used in the field of superconducting magnet devices.

It should be understood that the invention is not limited to the above-described embodiment, but may be modified into various forms on the basis of the spirit of the disclosure. Additionally, the modifications are included in the scope of the disclosure.

What is claimed is:

1. A superconducting magnet device comprising:
a cryostat that includes an inner peripheral wall disposed in a radially outward direction of a bore to surround the bore and an outer peripheral wall disposed in the radially outward direction of the inner peripheral wall to surround the inner peripheral wall, and that provides a vacuum environment in an internal space defined between the inner peripheral wall and the outer peripheral wall;
a pair of saddle superconducting coils disposed to face each other with the bore interposed between the pair of saddle superconducting coils, and each being exposed to the vacuum environment, in the internal space; and
a support frame that is disposed in the radially outward direction of the pair of saddle superconducting coils in the internal space, and that supports the pair of saddle superconducting coils.

2. The superconducting magnet device according to claim 1,
wherein the pair of saddle superconducting coils are disposed in a range of 1.05 to 1.32 times a diameter of the bore, in the internal space.

3. The superconducting magnet device according to claim 1,
wherein the pair of saddle superconducting coils are curved to be recessed toward the bore, and
the support frame includes a pair of coil mounts having a curved shape based on a curvature of the saddle superconducting coil, and a pair of linear coupling beams coupling the pair of coil mounts.

4. The superconducting magnet device according to claim 3,
wherein the pair of linear coupling beams have a smaller dimension in a vertical direction than a dimension of the pair of coil mounts.

5. The superconducting magnet device according to claim 3,
wherein the pair of linear coupling beams are disposed in a range of 1.05 to 1.32 times a diameter of the bore, in the internal space.

6. The superconducting magnet device according to claim 1, further comprising:
a horizontal load support body that supports the support frame in a horizontal direction,
wherein the support frame includes a recessed portion formed in a radially inward direction from an outer peripheral surface of the support frame, and is supported by the horizontal load support body with the recessed portion.

7. The superconducting magnet device according to claim 6,
wherein the horizontal load support body has a rod-like shape extending in a radial direction of the cryostat, is supported by a magnetic shield at one end of the horizontal load support body, and is supported by a coil mount of the support frame at the other end of the horizontal load support body.

8. The superconducting magnet device according to claim 7,
wherein both ends of the horizontal load support body are connected by a rod-shaped body formed of an insulating material.

9. The superconducting magnet device according to claim 1, further comprising:
a vertical load support body that supports the support frame in a vertical direction,
wherein the support frame includes a rib formed in the radially outward direction from an outer peripheral surface of the support frame and is supported by the vertical load support body with the rib.

10. The superconducting magnet device according to claim 9,
wherein the vertical load support body has a rod-like shape extending in the vertical direction, is supported on a bottom surface of the cryostat at one end of the vertical load support body, and is supported by a coil mount of the support frame at the other end of the vertical load support body.

11. The superconducting magnet device according to claim 10,
wherein both ends of the vertical load support body are connected by a rod-shaped body formed of an insulating material.

12. The superconducting magnet device according to claim 1, further comprising:
a first support attached to the support frame to press the saddle superconducting coil against the support frame in the radially outward direction.

13. The superconducting magnet device according to claim 1,
wherein each saddle superconducting coil includes a first coil end surface facing in the radially outward direction, a second coil end surface facing in a radially inward direction, and two coil side surfaces connecting the first coil end surface and the second coil end surface, and
the superconducting magnet device further comprises:
a second support attached to the support frame to sandwich the saddle superconducting coil between the two coil side surfaces.

14. The superconducting magnet device according to claim 1,
wherein the cryostat includes a pair of cryocoolers that cool the pair of saddle superconducting coils,
one of the pair of cryocoolers is installed in the cryostat on one side with respect to the bore between the pair of saddle superconducting coils in a circumferential direction of the cryostat, and
the other of the pair of cryocoolers is installed in the cryostat on an opposite side with respect to the bore between the pair of saddle superconducting coils in the circumferential direction of the cryostat.

15. The superconducting magnet device according to claim 14,
wherein the cryocooler includes a first cooling stage that is cooled to a first cooling temperature and a second cooling stage that is cooled to a second cooling temperature lower than the first cooling temperature.

16. The superconducting magnet device according to claim 15,
wherein the first cooling temperature is in a range of 30 K to 80 K, and the second cooling temperature is in a range of 3 K to 20 K.
